(19) United States
(12) Patent Application Publication
(10) Pub. No.: US 2014/0360545 A1
(43) Pub. Date: Dec. 11, 2014

(54) THERMOELECTRIC ENERGY CONVERTERS WITH REDUCED INTERFACE LOSSES AND MAUNFACTURING METHOD THEREOF

(71) Applicant: Uttam Ghoshal, Austin, TX (US)

(72) Inventor: Uttam Ghoshal, Austin, TX (US)

(73) Assignee: Sheetak, Inc., Austin, TX (US)

(21) Appl. No.: 14/117,355

(22) PCT Filed: May 3, 2012
(86) PCT No.: PCT/US12/36252

§ 371 Date: Nov. 19, 2013

Related U.S. Application Data
(60) Provisional application No. 61/518,620, filed on May 9, 2011.

(51) Int. Cl. H01L 35/32; H01L 35/34

(52) U.S. Cl. CPC H01L 35/32; H01L 35/34
USPC 136/200; 438/54; 136/201

(57) ABSTRACT

The present invention relates to a thermoelement for use in thermoelectric energy converters for power generation as well as cooling applications. The thermoelement includes a thermoelectric layer with a first side and a second side. Further, the thermoelement includes a first high power factor electrode and a second high power factor electrode. The first high power factor electrode is thermally and electrically attached to the first side of the thermoelectric layer and the second high power factor electrode is thermally and electrically attached to the second side of the thermoelectric layer. Furthermore, the thermoelement includes a plurality of metal layers. The plurality of metal layers are attached to the first high power factor electrode and the second high power factor electrode. In an embodiment of the present invention, a thermoelement comprises a plurality of micro thermoelements that are configured to reduce thermal density at the electrodes. In an embodiment of the present disclosure, the thermoelectric layer is hemispherical in shape, wherein the hemispherical thermoelectric layer is deposited in an etched metal layer.

### BACKGROUND

The present disclosure relates to the field of thermoelectric devices. More specifically, the present disclosure relates to thermoelectric devices with improved figure of merit and Coefficient of Performance (COP).

It is known in the art that solid-state thermoelectric energy converters can be used for cooling as well as power generation applications. Use of the thermoelectric energy converters in cooling applications i.e., to convert electrical energy to cooling effect, relates to Peltier effect, and the corresponding thermoelectric energy converters form a functional part of thermoelectric cooling devices. Alternatively, the solid-state thermoelectric energy converters can be used to recover thermal energy and generate thermoelectric power i.e., to use a temperature difference to generate electricity. This phenomenon relates to Seebeck effect, and the corresponding thermoelectric energy converters form a functional part of thermoelectric power generation devices. The efficiency of the thermoelectric energy converters is determined by the figure-of-merit (ZT) according to the equation:

$$ZT = \frac{σ {S}^{2}}{λ} \qquad ( 1 )$$

where ‘S’ is the thermopower, ‘σ’ is the effective electrical conductivity, and ‘X’ is the effective thermal conductivity of the materials. The traditional thermoelectric energy converters have ZT<1 and COP<1 for temperature differentials ΔT=25K. Higher ZT values result in efficient thermoelectric energy converters with higher COP.

The solid-state thermoelectric energy converters can effectively replace conventional vapor compression systems in cooling applications and mechanical engines in power generation applications, provided the figure of merit exceeds three (ZT>3). Further, the thermoelectric energy converters provide zero Green House Gases (GHGs) emission, a significant advantage over the conventional vapor compression systems used in cooling applications.

Efforts have been made in the past to increase the figure of merit of the thermoelectric energy converters by using materials such as nanostructured bismuth telluride that have improved thermoelectric properties. Thermoelectric energy converters with such improved materials provide a figure of merit of about 1.2 at room temperature and COP of 1.5 at temperature differential (ΔT) of 30K. However, these improvements in the figure of merit still do not make the thermoelectric energy converters competitive with the vapor compression systems in cooling applications and mechanical engines in power generation, applications.

Further, thermoelectric energy converters may comprise one or more thermoelements. More specifically, thermoelements with thin films have been developed to achieve high figure of merit in the thermoelectric energy converters. The thin film thermoelements suffer from losses at interfaces of different layers. Heat flux in the thermoelements is inversely proportional to transport length of the charge carriers. The thin film thermoelements usually have transport lengths equal to the thickness of the thermoelectric layer, thereby resulting in a high heat flux (˜10 kW/cm²). The high heat flux results in large parasitic temperature losses in disordered regions at the interlace of different layers of the thermoelectric energy converters. As a result of parasitic temperature losses, COP of the thermoelectric energy converters is affected. Further, in certain thin film thermoelements, up to one-third of temperature differential ΔT is lost at the interfaces because of high heat flux. Other efforts made to improve thin film thermoelements include reduction of thermal conductivity in superlattice planes, transport and confinement in nanowires and quantum dots, optimization of ternary and quaternary chalcogenides. In an alternate solution, advancements like vacuum tunneling devices, thermionic emissions and non equilibrium transport are provided in the devices using the thermoelements. However, in spite of these attempts to increase the figure of merit of the thermoelectric energy converters, there has been no significant improvement in practical devices.

Thus, there exists a need for further contributions for development in the domain of thermoelectric energy converters.

### SUMMARY

The present invention provides a thermoelectric energy converter with improved figure of merit. The thermoelectric energy converter comprises at least one thermoelement. An objective of the present invention is to provide a thermoelement of the thermoelectric energy converter with a high figure of merit for both cooling and power generation applications by reducing the interface losses at the interface of thermoelectric materials and the metal electrodes.

The present invention relates to a thermoelement for use in thermoelectric energy converters for power generation as well as cooling applications. The thermoelement includes a thermoelectric layer with a first side and a second side. Further, the thermoelement includes a first high power factor electrode and a second high power factor electrode. The first high power factor electrode is thermally and electrically attached to the first side of the thermoelectric layer and the second high power factor electrode is thermally and electrically attached to the second side of the thermoelectric layer. Furthermore, the thermoelement includes a plurality of metal layers. The plurality of metal layers are attached to the first high power factor electrode and the second high power factor electrode.

In another embodiment, a method for manufacturing a thermoelement is disclosed.

The method includes etching a base metal layer to form a predetermined shape. Further, the method includes depositing a first high power factor electrode on the base metal layer. Thereafter, a thermoelectric layer is deposited on the first high power factor electrode. Furthermore, the method includes depositing a second high power factor electrode on the thermoelectric layer. Moreover, the method includes annealing the layered structure comprising the base metal layer, the thermoelectric layer, the first high power electrode, and the second high power factor electrode to form a composition phase. Thereafter, a metal layer is deposited over the second high power factor electrode.

In another embodiment of the present invention, the thermoelement is geometrically shaped so as to provide a larger area for heat rejection at the hot end. In a particular embodiment, the thermoelement comprises a hemispherical layer. The hemispherical layer is made of a thermoelectric material with a first surface deposited on the first high power factor electrode. The second high power factor electrode is deposited on a second surface. A first metal layer is in contact with the first high power factor electrode, and the second metal layer is in contact with the second high power factor electrode.

In another embodiment of the present invention, a thermoelement comprises a plurality of micro thermoelements that are configured to reduce thermal density at the metal electrodes.

In another embodiment, a cold end interfaces are formed at an interfaces of the first high power factor electrode with the thermoelectric layer and the first metal layer, and wherein a hot end interfaces are formed at the interfaces of the second high power factor electrode with the thermoelectric layer and the second metal layer.

### BRIEF DESCRIPTION OF THE DRAWINGS

FIG. 1 is a schematic cross sectional view of a thermoelement, in accordance with an embodiment of the present invention;

FIG. 2 is a schematic diagram of a prior art thermoelement illustrating variation of Seebeck coefficient across the conventional thermoelement;

FIG. 3 is a schematic diagram illustrating variation of Seebeck coefficient across different layers of a thermoelement in accordance with an embodiment of the present invention;

FIG. 4 is a schematic perspective view of a thermoelement, in accordance with an embodiment of the present invention;

FIG. 5 is a schematic cross sectional view of a thermoelement in accordance with the same embodiment of the present invention;

FIG. 6 is a schematic diagram illustrating a cross section of a thermoelement in accordance with another embodiment of the present invention; and

FIG. 7 is a flowchart illustrating a method of manufacturing a thermoelement, in accordance with an embodiment of the present invention.

### DETAILED DESCRIPTION OF THE INVENTION

Before describing the embodiments in detail in accordance with the present disclosure, it should be observed that these embodiments reside primarily in the apparatus for thermoelectric cooling and power generation and the method for manufacturing it. Accordingly, the method steps and the system components have been represented to show only those specific details that are pertinent for an understanding of the embodiments of the present invention, and not the details that will be apparent to those with ordinary skill in the art.

Definitions to be highlighted before describing the present disclosure in detail are:

Definition of Chalcogenides: Chalcogenides are compounds of a combination of one of the elements of group 16 of the periodic table and at least one electropositive element.

Power factor: The power factor of a thermoelectric material or metal is the product of the square of the Seebeck coefficient and the electrical conductivity of the material (P=σS²)

List of Acronyms used in the present disclosure:

PVD: Physical Vapor Deposition;

CVD: Chemical Vapor Deposition;

TE films: Thermoelectric films.

COP: Coefficient of Performance

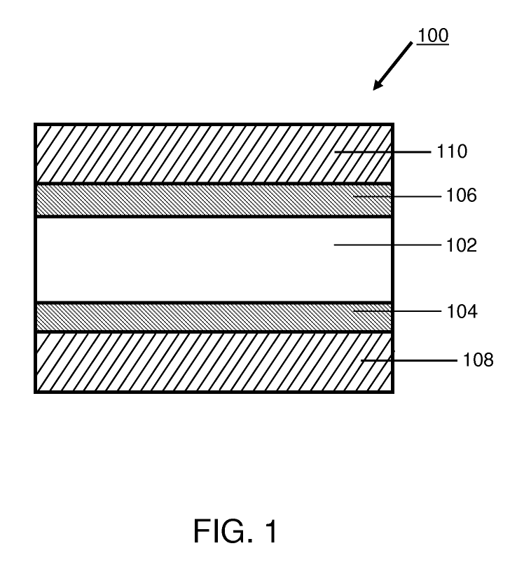

FIG. 1 is a schematic cross sectional view of a thermoelement 100, in accordance with an embodiment of the present disclosure.

In an embodiment of the present disclosure, thermoelement 100 is a thin film thermoelement that is used in thermoelectric energy converters in cooling and power generation applications. Thermoelement 100 comprises a thermoelectric layer 102, a first high power factor electrode 104, a second high power factor electrode 106, a first metal layer 108 and a second metal layer 110.

In accordance with an embodiment, high power factor electrodes 104 and 106 are layers made of material having high thermopower, i.e., Seebeck coefficient in the range 100-250 μV/K.

A first side of thermoelectric layer 102 is attached to first high power factor electrode 104 and a second side of thermoelectric layer 102 is attached to second high power factor electrode 106. Further, first metal layer 108 is attached to first high power factor electrode 104 and second metal layer 110 is attached to second high power factor electrode 106.

In an embodiment of the present invention, thermoelectric layer 102 is made of a p-type semiconductor material such as Bi—Sb—Te chalcogenides

(Bismuth-Antimony-Telluride Chalcogenides) or n-type semiconductor material such as Bi—Te—Se (Bismuth-Telluride-Selenide Chalcogenides). Thermoelement 100 made of such materials typically finds application in, but not limited to, refrigeration, air-conditioning, battery cooling and distillation applications. In another embodiment of the present invention, thermoelectric layer 102 is made of a n-type semiconductor material such as LAST (Lead, Silver, Antimony and Tellurium compound e.g. Pb₁₈AgSbTe₂₀) or skutterudites such as Ba_{0.08}Yb_{0.09}Co₄Sb₁₂) or p-type semiconductor material such as Zn₄Sb₃ or CeFe_{3.5}Co_{0.5}Sb₁₂. Thermoelement 100 made of LAST or Zn₄Sb₃ is typically used in energy recovery applications such as generating electricity from automobile exhausts, diesel generators, fuel cell exhausts and power plant steam.

In an embodiment of the present invention, high power factor electrodes 104 and 106 have a high thermopower (i.e. the Seebeck coefficient approximately equal to 150 μV/K), high electrical conductivity similar to metals such as molybdenum, aluminum or the like, (i.e., greater than 10⁶ S/m), and high thermal conductivity similar to metals such as molybdenum, aluminum or the like (i.e., greater than 10 W/m-K). In another embodiment of the present invention, materials used in high power factor electrodes 104 and 106 are Kondo intermetallics, YbAl₃ (Ytterbium-Aluminum) with n-type thermoelectric materials or CePd₃ (Cerium-Palladium) with p-type thermoelectric materials. The materials as described in the above embodiments have thermopower approximately equal to 110-140 μV/K and the electronic power factors (σS²) of approximately 0.018 WK⁻² m⁻¹ for YbAl₃ and 0.01 WK⁻² m⁻¹ for CePd₃, which are of higher order as compared to other materials. Further, YbAl₃ and CePd₃ also have very high thermal conductivity (˜10 Wm⁻¹K⁻¹) and electrical conductivity (˜2 S/μm) as compared to those of thermoelectric materials.

In another embodiment of the present invention, high power factor electrodes 104 and 106 are made of semi-metals or semiconductor materials such as Bi, Sb, InSb and CoSb₃. These materials have a good Seebeck coefficient and good electrical conductivity but high thermal conductivity.

In an embodiment of the present invention, first metal layer 108 and second metal layer 110 are configured to spread the heat and reduce the heat flux across thermoelement 100. In an exemplary embodiment, first metal layer 108 and the second metal layer 110 may be made of refractory metals such as molybdenum or tungsten. In another exemplary embodiment, first metal layer 108 and second metal layer 110 may be made of refractory materials coated with metals such as copper, nickel, aluminum, gold, silver.

In an embodiment of the present invention, thermoelement 100 is used in cooling applications in an operating temperature range of about −50° C. to 100° C.

For instance, thermoelectric layer 102 may be made of a thermoelectric material such as Bi_{0.5}Sb_{1.5}Te₃, Bi₂Te₃, and InSb. Thermoelement 100 described in the present embodiment may be used in refrigeration, air-conditioning, battery cooling and distillation applications or the like.

In another embodiment of the present invention, the thermoelement is used in power generation applications at an operating temperature range of about 100° C. to about 500° C. For example, thermoelectric layer 102 of thermoelement 100 may be made of materials such as Zn—Sb and/or Pb₁₈AgSbTe₂₀ (LAST—Plumbum, Argentum, Stibium and Tellurium) or the like. Thermoelement 100 of the present embodiment may be used in energy recovery applications such as generating electricity from automobile exhausts, diesel generators, fuel cell exhausts and power plant steam or the like.

In yet another embodiment of the present invention, thermoelement 100 is used in power generation applications at an operating temperature range of about 400° C. to about 800° C. For example, thermoelectric layer 102 of thermoelement 100 may be made of materials such as Si, SiGe, silicides such as Mg₂Si, skutteridites based on CoSb3, and rare-earth tellurides such as La₃-xYbyTe₄. Further, thermoelement 100 may be used in power generation applications such as in gas turbine exhaust, combustion generators, concentrated solar applications and hybrid solar applications with the operating temperature range of about 400° C. to 800° C.

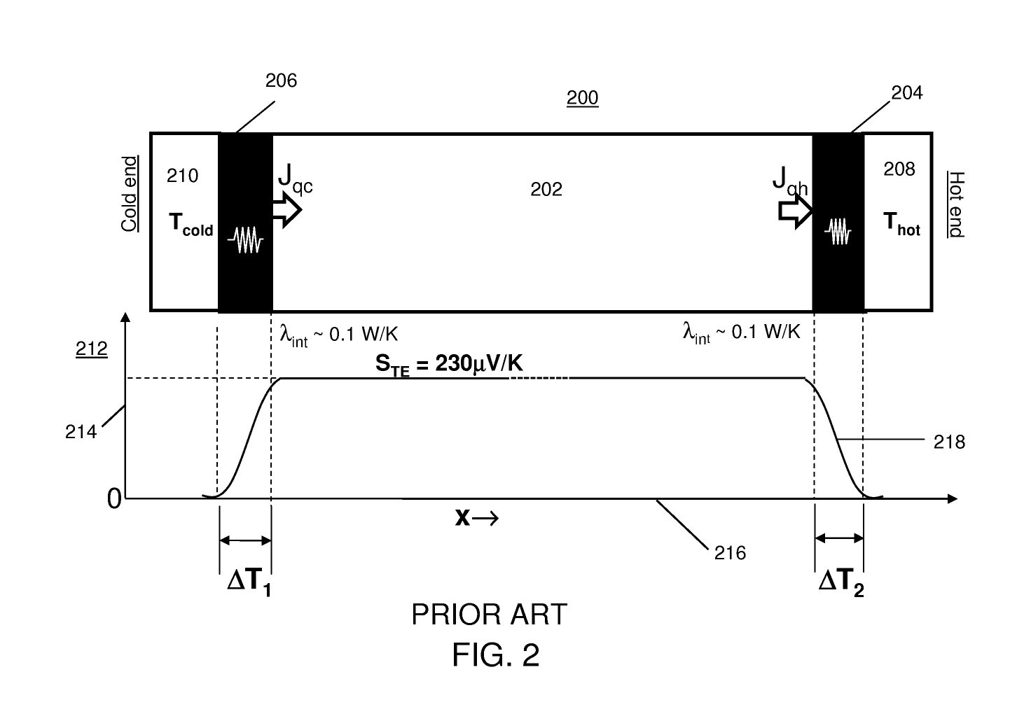

FIG. 2 is a schematic diagram of a prior art thermoelement illustrating variation of Seebeck coefficient across the conventional thermoelement 200.

Conventional thermoelement 200 typically comprises a thermoelectric layer 202, a first interface 204, a second interface 206, a first metal layer 208 and a second metal layer 210. In this embodiment of the present invention, conventional thermoelement 200 is used in a thermoelectric energy converter for a cooling application such as refrigeration, air conditioning, battery cooling or the like.

A graph 212 depicts variation of Seebeck coefficient across various layers of conventional thermoelement 200. Y-axis 214 represents magnitude of Seebeck coefficient and X-axis 216 represents different layers of conventional thermoelement 200. A curve 218 represents the variation of thermopower (the Seebeck coefficient) across conventional thermoelement 200.

Curve 218 depicts that Seebeck coefficient changes abruptly at interfaces 204 and 206. The thermopower (S_{TE}) of the illustrative thermoelectric layer 202 is approximately equal to 230 μV/K, whereas thermopower of metal layers 208 and 210 is approximately equal to 0 μV/K. This change in thermopower across interfaces 204 and 206 results in heat absorption and rejection in the disordered regions and causes a large temperature drop across interfaces 204 and 206. The temperature drops as depicted in graph 212 have a direct impact on the COP of thermoelectric energy converters utilizing thermoelement 200. The following analysis estimates the temperature drops under practical operating conditions of thermoelement 200:

The cooling flux (J_{qc}) at a cold end (as denoted in FIG. 2) and the heat flux (J_{qh}) at a hot end (as denoted in FIG. 2) of thermoelement 200 operating under the maximum temperature differential mode (for example ΔT=ΔTₘₐₓ, Q (cooling power)=0, COP=0) are given by the relations:

$$\begin{matrix}{J}_{qc} = 0 & ( 1 ) \\ {J}_{qh} = \frac{σ ( {S}_{TE} {T}_{cmin} )}{t} & ( 2 )\end{matrix}$$

where T_{cmin} is the absolute temperature of the cold end for the maximum cooling and ‘t’ is the thickness of the thermoelectric layer 202. For typical values, S_{TE}=230 μV/K, σ=0.05 S/μm, t=1 μm, and T_{cmin}=230K, J_{qh}=140 μW/μm² or equivalently, 14 kW/cm².
The temperature drop ΔT₁ across the interface 206 on the cold end and the temperature drop ΔT₂ across interface 204 at the hot end of conventional thermoelement 200 are given by:

$$\begin{matrix}Δ {T}_{1} = \frac{{J}_{qc} {t}_{int}}{{λ}_{int}} \sim 0 & ( 3 ) \\ Δ {T}_{2} = \frac{{J}_{qh} {t}_{int}}{{λ}_{int}} & ( 4 )\end{matrix}$$

where tᵢₙₜ is the thickness of interfaces 204 and 206, and λLᵢₙₜ is the thermal conductivity of interface regions 204 and 206. Typically, interface thickness tᵢₙₜ may be of the order of 30 nm. For example, when thermal conductivity of interfaces 204 and 206 is λᵢₙₜ=0.1 W/m-K (low thermal conductivity due to disordered material structure and atomic weight mismatches), temperature drop (ΔT₂) is approximately equal to 40 K and thickness of interface (tᵢₙₜ) is approximately 30 nm, the maximum temperature differential ΔTₘₐₓ of the device is significantly reduced from 70K to 30K due to losses at interfaces 204 and 206.

In another example, when thermoelement 200 is operated under conditions such as temperature drop ΔT is equal to 0.5 ΔTₘₐₓ and COP of thermoelectric energy converter is approximately equal to 0.8, the cooling power density at cold end (as denoted in FIG. 2) J_{qc} and the heat flux rejected at hot end (as denoted in FIG. 2) J_{qh}, are given by the following equations:

$$\begin{matrix}{J}_{qc} \sim 0.12 \frac{{σ ( {S}_{TE} {T}_{cmin} )}^{2}}{t} & ( 5 ) \\ {J}_{qh} = {J}_{qc} ( 1 + \frac{1}{COP} ) \sim 0.28 \frac{{σ ( {S}_{TE} {t}_{cmin} )}^{2}}{t} & ( 6 )\end{matrix}$$

Further, the temperature drop ΔT₁ across interface 206 on the cold end and the temperature drop ΔT₂ across interface 204 at the hot end for maximum COP conditions are given by:

$$\begin{matrix}Δ {T}_{1} = \frac{{J}_{qc} {t}_{int}}{{λ}_{int}} & ( 7 ) \\ Δ {T}_{2} = \frac{{J}_{qh} {t}_{int}}{{λ}_{int}} & ( 8 )\end{matrix}$$

For example, when we substitute typical values, the temperature drop at first interface 204 (ΔT₁)=5K and the temperature drop at second interface 206 (ΔT₂)=13K, and the maximum temperature drop ΔTₘₐₓ of the thermoelement 200 is reduced by approximately 18K (sum of ΔT₁ and ΔT₂).

The large parasitic temperature drops at interfaces 204 and 206 results in a significantly lower COP. The temperature losses at interfaces 204 and 206 may render thin film thermoelectric devices impractical for cooling and power generation applications.

The Table I below summarizes properties of thermoelement 200.

TABLE I
Thermoelements Without High Power Electrodes

| | | | | | Net |
|---|---|---|---|---|---|
| | | | Interface | Interface | Reduction |
| | Cooling Density | Heat Flux | Losses at | Loss at | in |
| | at Cold End | at Hot End | Cold End | Hot End | ΔT (=ΔT₁ + |
| Operation Mode | J_{qc} (kW/cm²) | J_{qh} (kW/cm²) | ΔT₁ (K) | ΔT₂(K) | ΔT₂) |
| Maximum | 0 | 14 | 0 | 40 | 40 |
| ΔT | | | | | |
| (ΔT = ΔTₘₐₓ, | | | | | |
| COP = 0) | | | | | |
| Maximum COP | 1.7 | 3.9 | 5 | 13 | 18 |
| (ΔT = 0.5 | | | | | |
| ΔTₘₐₓ = | | | | | |
| 35 K, COP = 0.8) | | | | | |

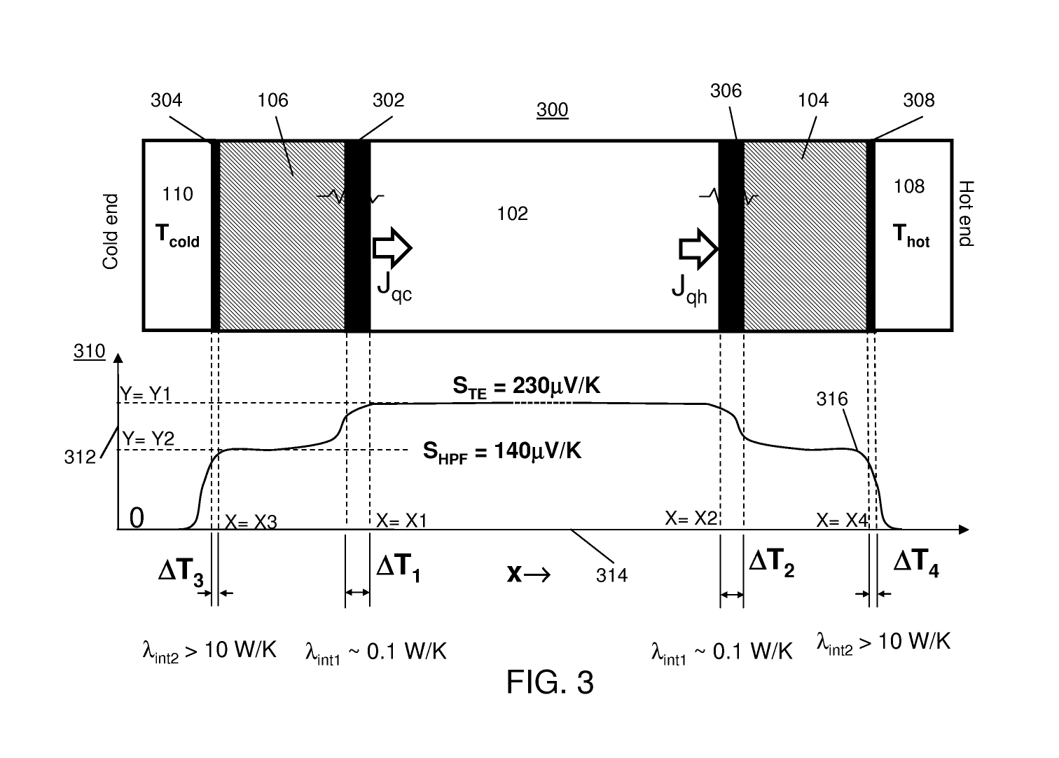

FIG. 3 is a schematic diagram illustrating variation of Seebeck coefficient across different layers of a thermoelement 300 in accordance with an embodiment of the disclosed invention.

Thermoelement 300 comprises a thermoelectric layer 102, a first high power factor electrode 104, a second high power factor electrode 106, a first metal layer 108 and a second metal layer 110, cold end interfaces 302 and 304 and hot end interfaces 306 and 308.

In an embodiment of the present disclosure, in thermoelement 300, high power factor electrodes 104 and 106 are configured to electrically and thermally connect thermoelectric layer 102 to metal layers 108 and 110, respectively. The hot end interface 306 is formed between thermoelectric layer 102 and first high power factor electrode 104, whereas, the hot end interface 308 is formed between the first high power factor electrode 104 and the first metal layer 108.

Further, the cold end interface 302 is formed between thermoelectric layer 102 and the second high power factor electrode 106, whereas, the cold end interface 304 is formed between the second high power factor electrode 106 and the second metal layer 110.

In an embodiment of the present disclosure, the interfaces 302 and 306 may be disordered regions with low thermal conductivity (for example, λᵢₙᵢₜ₁˜0.1 W/m-K) whereas interfaces 304 and 308 may be metallic regions with higher thermal conductivity (for example, λᵢₙₜ₂>10.0 W/m-K).

A graph 310 is plotted with Seebeck coefficient (taken as Y-axis 312) against different layers of thermoelement 300 (taken as X-axis 314). A curve 316 represents variation of Seebeck coefficient across different layers of thermoelement 300. Seebeck coefficient directly relates to thermopower of different layers of thermoelement 300.

At Y=Y1, the thermopower of thermoelectric layer 102 (between X=X1 to X=X2) is approximately equal to 230 μV/K. At Y=Y2, the thermopower of high power factor electrodes 104 and 106 (between X=X1 to X=X3 and X=X2 to X=X4) is approximately equal to 140 μV/K. At X=X3 which represents cold end interface 304 and at X=X4 which represents hot end interface 308, the thermopower starts to decrease and soon falls to zero. Thus, at different layers of thermoelement 300, the magnitude of thermopower varies along with temperature drop, and this variation of thermopower has a direct impact on COP of thermoelectric energy converters utilizing thermoelement 300.

Further, the high thermopower in high power factor electrodes 104 and 106 reduces the gradient of the thermopower in interfaces 306 and 302 between thermoelectric layer 102 and high power factor electrodes 104 and 106, thereby translating the spatial location of heat rejection or absorption to the interface region between high power factor electrodes 104 and 106 and metal layers 108 and 110 respectively. The temperature losses in these high conductivity regions are significantly lower because interfaces 304 and 308 are diffused metallic regions and thermal conductance is primarily by electron transport.

Furthermore, as per the Thompson's effect, the thermoelectric cooling or heating flux (J_{qTE}) at the interfaces of thermoelement 300 is proportional to the spatial gradient of thermopower at each interface and the variation is given by the following expression,

$${J}_{qTE} = T ( J \cdot ∇ S ) = TJ \frac{d S}{d x} \qquad ( 9 )$$

where, ‘J’ is the current density, ‘dS/dx’ is the gradient of the thermopower, and T is temperature in Kelvin scale at each of the interfaces 302, 304, 306, and 308. In the case of thermoelement 300 being operated under the maximum temperature differential conditions (ΔT=ΔTₘₐₓ, Q=0, COP=0), the temperature drops ΔT₁ at X=X1 and ΔT₃ at X=X3 across the interfaces 302 and 304 on the cold end and the temperature drops ΔT₂ at X=X2 and ΔT₄ at X=X4 across the interfaces 306 and 308 at the hot end are given by:

$$\begin{matrix}Δ {T}_{1} = 0 & ( 10 ) \\ Δ {T}_{3} = 0 & ( 11 ) \\ Δ {T}_{2} \sim \frac{( {S}_{TE} - {S}_{HPF} )}{{S}_{TE}} \cdot \frac{{J}_{qh} {t}_{int}}{{λ}_{int 1}} & ( 12 ) \\ Δ {T}_{4} \sim \frac{{S}_{HPF}}{{S}_{TE}} \frac{{J}_{qh} {t}_{int}}{{λ}_{int 2}} & ( 13 )\end{matrix}$$

For instance, if heat flux at the hot end of thermoelement 300, J_{qh}=14 kW/cm², Seebeck coefficient at thermoelectric layer 102, S_{TE}=230 μV/K, Seebeck coefficient at high power factor electrodes 104 and 106 S_{HPF}=140 μV/K, thickness of interface, tᵢₙₜ=30 nm, thermal conductivity at hot end interface 306 λᵢₙₜ₁=0.1 W/m-K and thermal conductivity at hot end interface 308 λᵢₙₜ₂=10 W/m-K for the maximum temperature differential operating conditions (ΔT=ΔTₘₐₓ, Q=0, COP=0), then we get ΔT₂=16 K at X=X2 and ΔT₄=0.4 K at X=X4. Hence the temperature losses at the interfaces in thermoelement 300 under the maximum temperature differential conditions are scaled down by a factor of approximately about 2.5 when compared to thermoelement 200.

In another example, when thermoelement 300 is being operated under the maximum COP conditions (for example, ΔT=0.5 ΔTₘₐₓ=35K, COP=0.8), the temperature drops ΔT₁ at X=X1 and ΔT₃ at X=X3 across the interfaces 302 and 304 on the cold end and the temperature drops ΔT₂ at X=X2 and ΔT₄ at X=X4 across interfaces 306 and 308 at the hot end are given by:

$$\begin{matrix}Δ {T}_{1} = \frac{( {S}_{TE} - {S}_{HPF} )}{{S}_{TE}} \cdot \frac{{J}_{qc} {t}_{int}}{{λ}_{int 1}} & ( 14 ) \\ Δ {T}_{3} = \frac{{S}_{HPF}}{{S}_{TE}} \frac{{J}_{qc} {t}_{int}}{{λ}_{int 2}} & ( 15 ) \\ Δ {T}_{2} \sim \frac{( {S}_{TE} - {S}_{HPF} )}{{S}_{TE}} \cdot \frac{{J}_{qh} {t}_{int}}{{λ}_{int 1}} & ( 16 ) \\ Δ {T}_{4} \sim \frac{{S}_{HPF}}{{S}_{TE}} \frac{{J}_{qh} {t}_{int}}{{λ}_{int 2}} & ( 17 )\end{matrix}$$

In a yet another example, when cooling flux at the cold end of thermoelement 300 J_{qc}=1.7 kW/cm², heat flux at the hot end of thermoelement 300 J_{qh}=3.9 kW/cm², Seebeck coefficient at thermoelectric layer 102 S_{TE}=230 μV/K, Seebeck coefficient at high power factor electrodes 104 and 106 S_{HPF}=140 μV/K, thickness of interface tᵢₙₜ=30 nm, thermal conductivity at X=X1=0.1 W/m-K and thermal conductivity at X=X2 Xᵢₙₜ₂=10 W/m-K for the maximum COP conditions (ΔT=0.5 ΔTₘₐₓ=35K, COP=0.8), we get a temperature drop at X=X1 of ΔT₁=2 K, a temperature drop at X=X3 of ΔT₃=0.05 K, a temperature drop at X=X2 of ΔT₂=4.6 K and a temperature drop at X=X4 of ΔT₄=0.1 K. Hence, the temperature losses at interfaces 302, 304, 306 and 308 in the thermoelement 300 are scaled down by a factor of 3 when compared to temperature losses at interfaces 204 and 206 of thermoelement 200. Table II summarizes corresponding interface losses in thermoelement 300 with high power electrodes 104 and 106.

TABLE II
Thermoelements With High Power Electrodes

| | | | Interface | Interface | Net |
|---|---|---|---|---|---|
| | | | Losses at | Loss at | Reduction in |
| | Cooling Density | Heat Flux | Cold End | Hot End | ΔT (=ΔT₁ + |
| | at Cold End | at Hot End | ΔT₁ + ΔT₃ | ΔT₂ + ΔT₄ | ΔT₃ |
| Operation Mode | J_{qc} (kW/cm²) | J_{qh} (kW/cm²) | (K) | (K) | ΔT₂ + ΔT₄) (K) |
| Maximum | 0 | 14 | 0 | 16.4 | 16.4 |
| ΔT | | | | | |
| (ΔT = ΔTₘₐₓ, | | | | | |
| COP = 0) | | | | | |
| Maximum COP | 1.7 | 3.9 | 2 | 4.7 | 6.7 |
| (ΔT = 0.5 | | | | | |
| ΔTₘₐₓ = | | | | | |
| 35 K, COP = 0.8) | | | | | |

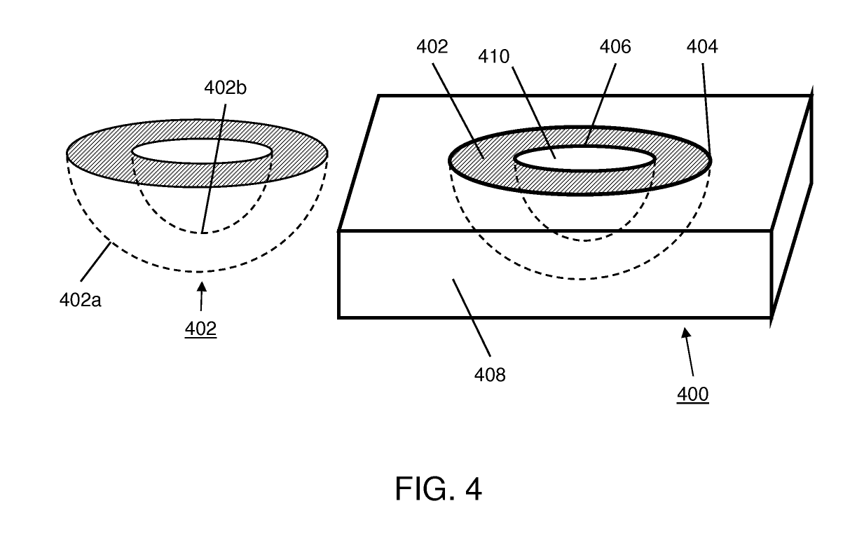

FIG. 4 is a schematic perspective view of a thermoelement 400, in accordance with another embodiment of the present invention.

In accordance with this embodiment, thermoelement 400 comprises a hemispherical thermoelectric layer 402, a first high power factor electrode 404, a second high power factor electrode 406, a first metal layer 408 and a second metal layer 410.

The hemispherical thermoelectric layer 402 is provided with a convex surface 402a and a concave surface 402b. The first metal layer 408 acts as a base metal layer. The base metal layer 408 is etched to form a predetermined shape. In other words, the base metal layer is etched to form a hemispherical pit to conform to the shape of the convex side 402a of the thermoelectric layer 402. Alternatively, any suitable method can be applied to form a base metal layer or metal carrier wafers or foils such as Ni, W, Ta, or Mo into geometric shapes such as hemispherical pits.

The convex surface 402a of hemispherical thermoelectric layer 402 covers a first high power factor electrode 404. The concave curved surface 402b of hemispherical thermoelectric layer 402 is covered with the second high power factor electrode 406. The first metal layer 408 is present below the first high power factor electrode 404 and the second metal layer 410 covers the second high power factor electrode 406. The first metal layer 408 is configured to withstand high temperatures during annealing and generally have low coefficient of thermal expansion. In an embodiment of this invention, the outer metal layer 408 is a refractory metal such as molybdenum or tungsten.

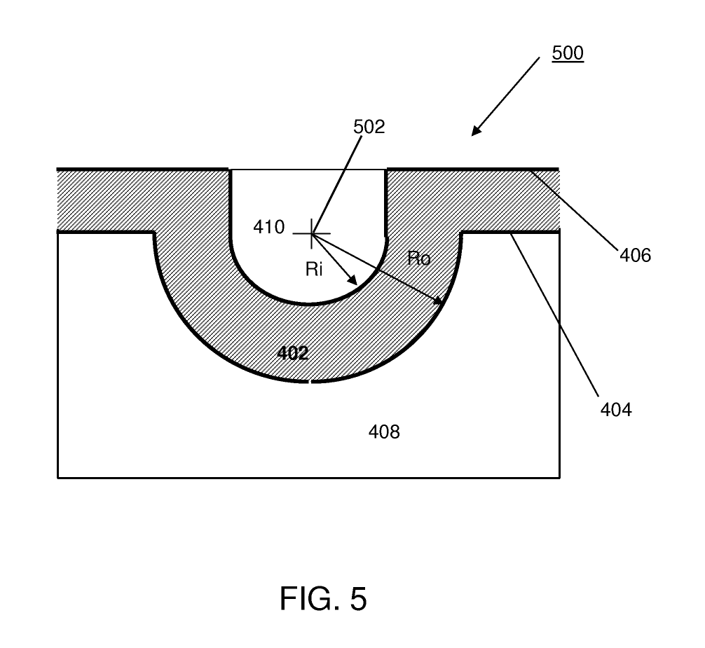

FIG. 5 is a schematic cross sectional view of the embodiment shown in FIG. 4 and labeled as thermoelement 500.

In FIG. 5, a point 502 is assumed as a reference to determine inner and outer radius labeled as Rᵢ and Rₒ in FIG. 5. ‘Rₒ’ (outer radius) is the distance between point 502 and a layer of first high power factor electrode 404, and ‘Rᵢ’ (inner radius) is the distance between point 502 and a layer of second high power factor electrode 406 and, as shown in the figure.

Furthermore, in an embodiment of the present disclosure, the first metal layer 408 and the second metal layer 410 forms the hot end and cold end of thermoelement 500, respectively, when thermoelement 500 is used for cooling and related applications. The ratio of the (outer) surface area of the hot end (Aₕ) of thermoelement 500 to that of the (inner) surface area of the cold end (A_{c}) is designed such that the ratio equals the ratio of heat rejected at the hot end to the cooling power at the cold end. For an illustrative purpose, the ratio between areas of the hot end and the cold end (Aₕ/A_{c}) equals

$$1 + \frac{1}{COP}$$

at an operating point (not shown in the figure) of thermoelement 500 in the cooling mode. When thermoelement 500 is operated in the power generation mode, the ratio between areas of the hot end and the cold end (Aₕ/A_{c}) equals

$$\frac{1}{1 - ɛ} ,$$

where ε is the efficiency of an energy converter device utilizing thermoelement 500.

As an illustrative example, the relationship between the ratio of hot end heat flux (J_{qh}) and cold end heat flux (J_{qc}) and the ratio of areas of cold end and hot end (A_{c}/Aₕ) is given by the relation:

$$\frac{{J}_{qh}}{{J}_{qc}} = ( 1 + \frac{1}{COP} ) \cdot \frac{{A}_{c}}{{A}_{h}} = ( 1 + \frac{1}{COP} ) \cdot {( \frac{{R}_{i}}{{R}_{o}} )}^{2} \qquad ( 18 )$$

For example, when COP of thermoelectric energy converter in which thermoelement 500 is used is 1, Rᵢ=3 μm, and Rₒ=5 μm, then the ratio between heat flux of hot end and cold end, given as (J_{qh}/J_{qc}), is 0.7. Hence, the influence of design of thermoelements such as thermoelement 500 has a direct impact over the heat density at the hot or cold end of thermoelement 500.

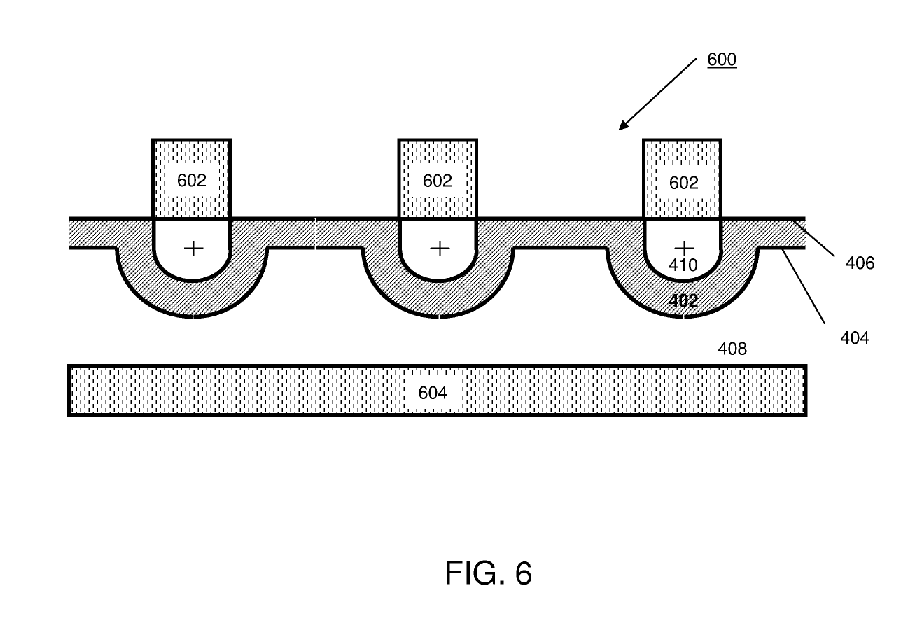

FIG. 6 illustrates a schematic cross sectional view of a thermoelement 600 in accordance with an embodiment of the present invention.

Thermoelement 600 comprises most of the elements in common with thermoelement 400 and 500 except metal structures 602 and a flat metal layer 604.

Thermoelement 600 comprises multiple portions of hemispherical thermoelectric layer 402. In other words, a plurality of micro thermoelements are combined together to form a macro thermoelement 600. High power factor electrodes 404 and 406 connect hemispherical thermoelectric layer 402 to metal layers 408 and 410. Metal structures 602 are in contact with inner metal layer 410. In an embodiment of the present invention, metal structures 602 are cylindrical in shape. Flat metal layer 604 is in contact with metal layer 408 and is deposited through a process for example, of electroplating or the like.

Further, in an embodiment, a plurality of micro thermoelements are combined together to form a macro thermoelement 600. In other words, the micro thermoelements are smaller in size as compared to the thermoelement 200 or 400. These, micro thermoelements are combined together such that they share the flat metal layer 604 as a common base.

A plurality of hemispherical micro thermoelectric layers can also be utilized to reduce the temperature loss in the metal layers 408 and 604 when compared to single hemispherical embodiment such as thermoelement 500. Consider an example wherein the thermoelement 500 has the outer radius R_{single} and the thermoelement 600 with equivalent cooling power has ‘N’ number of hemispherical structures with outer radius Rₘᵤₗₜᵢₚₗₑ. The temperature drop ΔT_{single} in the metal layers 408 of thermoelement 500 with metal layer thickness greater than the radius R_{single}, and the temperature drop ΔTₘᵤₗₜᵢₚₗₑ in the metal layers 410 of thermoelement 600 with metal layer thickness greater than the radius Rₘᵤₗₜᵢₚₗₑ are given by:

$$\begin{matrix}Δ {T}_{single} = \frac{{J}_{qh} {R}_{single}}{{λ}_{metal}} & ( 19 ) \\ Δ {T}_{multiple} = \frac{{J}_{qh} {R}_{multiple}}{{λ}_{metal}} & ( 20 )\end{matrix}$$

where J_{qh} is the heat flux density at the hot side of the thermoelectric layer 402 and λₘₑₜₐₗ is the thermal conductivity of the metal layer 408. In the case wherein the thermoelement 500 and thermoelement 600 have the same cooling powers,

J_{qh}(πR_{single}²)=NJ_{qh}(πRₘᵤₗₜᵢₚₗₑ²) (21)

or equivalently,

$${R}_{multiple} = \frac{{R}_{single}}{\sqrt{N}} \qquad ( 22 )$$

Substituting the above relation from equation (22) in equation (19) and (20), we get

$$Δ {T}_{multiple} = \frac{Δ {T}_{single}}{\sqrt{N}} \qquad ( 23 )$$

Hence the temperature losses in the metal layer 408 can be significantly reduced in thermoelement 600 by using large number of microscopic hemispherical structures (say, N=100).

In an embodiment of the present invention, metal structures 602 are deposited through a process of patterning photoresists by photolithography and electroplating. The metal structures 602 are typically 1 micrometer to 50 micrometer in thickness. In an embodiment of the present disclosure, metal structures 602 are made of metals such as copper, nickel, silver, platinum, or gold.

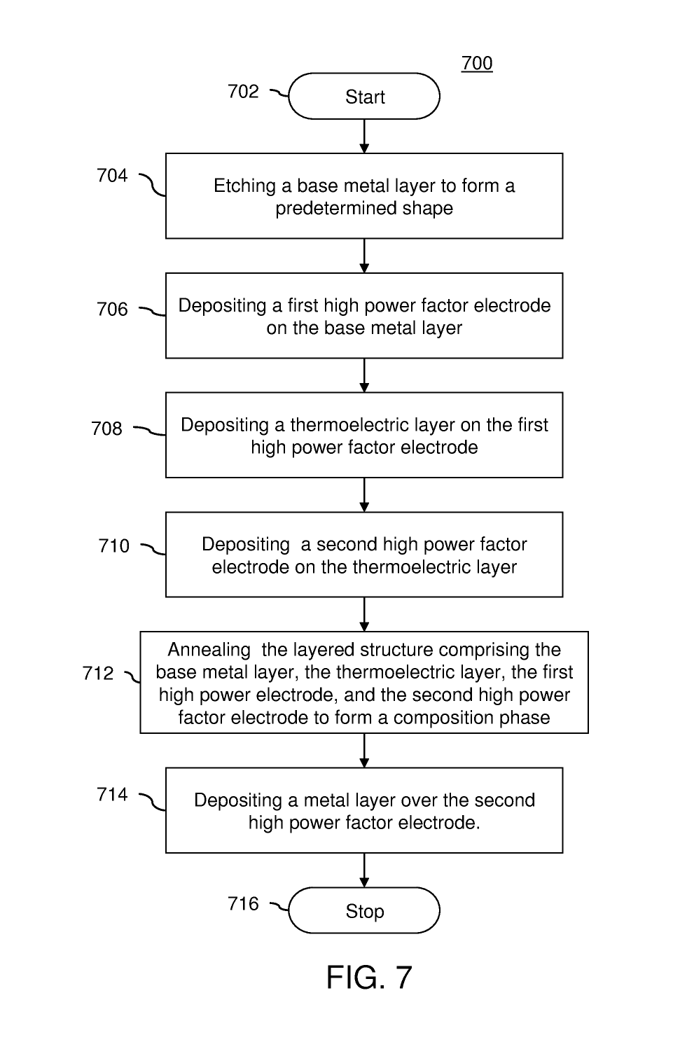

FIG. 7 is a flowchart illustrating a method 700 of manufacturing a thermoelement, in accordance with an embodiment of the present invention.

The method starts at a step 702. At a step 704 a base metal layer is etched to form a predetermined shape. In other words a first metal layer is provided. In an embodiment, the first metal layer is etched so as to conform with a predetermined shape. The shape of the metal layer can be modified in order to obtain different surface area for the thermoelement.

Thereafter, at step 706 a first high power factor electrode is deposited on the base metal layer. In an embodiment of the present disclosure, materials such as YbAl₃ or InSb or CoSb₃ for an n-type thermoelement and CePd₃ for a p-type thermoelement may be deposited as the high power factor electrode. The deposition of the high power factor electrode on the thermoelectric layer is carried out by a method such as magnetron sputtering or other physical vapor deposition (PVD).

Further, in an embodiment of the present disclosure, for a thermoelement comprising a hemispherical thermoelectric layer, etching is performed on the base metal layer before depositing the first and the second high power factor electrode in order to position the hemispherical thermoelectric layer. In this embodiment of the present disclosure, a Mo or W foil of about 20 μm thickness is used as a base metal layer.

Thereafter, at step 708, a thermoelectric layer is deposited on the first high power factor electrode by a method such as magnetron sputtering. In an embodiment of the present disclosure, one or more thermoelectric materials such as Bi_{0.5}Sb_{1.5}Te₃, Bi₂Te₃, Zn₄Sb₃ and LAST are used in the thermoelectric layer. Further at step 710, a second high power factor electrode is deposited on the thermoelectric layer.

Thereafter, at step 712, the layered structure comprising the base metal layer, the thermoelectric layer, the first high power electrode, and the second high power factor electrode is annealed to form a composition phase. In other words, the composite structure is heat treated to form a composition phase. For example, the composite structure is annealed to allow proper grain growth, and thereafter quenching allows proper nanostructure to be established in the thermoelectric layer.

Thereafter, at step 714, a metal layer is deposited over the second high power factor electrode. In an embodiment, the metal layer is deposited by using metal organic chemical vapor deposition (MOCVD). In another embodiment of the present disclosure, metal layers are deposited by electroplating.

Thereafter, in an embodiment, the thermoelement is diced or etched to form units of thermoelements of required dimensions. In an embodiment of the present disclosure, dicing is performed using a diamond blade or using a laser beam.

Further, the method is terminated at step 716.

The thermoelements and the thermoelectric devices described in various embodiments of the present disclosure provide high efficiency energy conversion. The thermoelement described in various embodiments of the present disclosure can be used in cooling applications, power generation applications and energy recovery applications.

The present disclosure provides thermoelements that have low manufacturing cost and can be manufactured in high volume.

It should be noted that applications of the device or the thermoelements described herein, in accordance with the various embodiments of the present disclosure, should not be taken as limitations. The thermoelement or the device could find applications that are not mentioned or described in the present disclosure that are known to the person skilled in the art.

While the preferred embodiments of the invention have been illustrated and described, it will be clear that the invention is not limited to these embodiments only. Numerous modifications, changes, variations, substitutions, and equivalents will be apparent to those skilled in the art without departing from the spirit and scope of the invention.

What is claimed is:

1. A thermoelement, the thermoelement comprising:
a thermoelectric layer with a first side and a second side;
a first high power factor electrode and a second high power factor electrode, wherein the first high power factor electrode is thermally and electrically attached to the first side of the thermoelectric layer and the second high power factor electrode is thermally and electrically attached to the second side of the thermoelectric layer; and
a plurality of metal layers attached to the first high power factor electrode and the second high power factor electrode.

2. The thermoelement as recited in claim 1, wherein the thermoelectric layer is a composite layer comprising a plurality of thermoelectric layers.

3. The thermoelement as recited in claim 1, wherein the first and the second high power factor electrode are Kondo intermetallics.

4. The thermoelement as recited in claim 1, wherein the first and the second high power factor electrode are semiconductors with magnitude of Seebeck coefficient greater than 50 microVolt per Kelvin (μV/K).

5. The thermoelement as recited in claim 1, wherein the first and the second high power factor electrode is selected from a group consisting of CoSb3 (Cobalt Antimonide), InSb (Indium Antimonide), YbAl3 (Ytterbium Aluminide), CePd3 (Cerium Palladide), Bi (Bismuth), and Sb (Antimony).

6. The thermoelement as recited in claim 1, wherein the plurality of metal layers are refractory metal.

7. The thermoelement as recited in claim 1, wherein the plurality of metal layers have thermal conductivity greater than 50 Watts per meter Kelvin (W/m-K).

8. The thermoelement as recited in claim 1, wherein the thermoelement is geometrically shaped to provide maximum heat rejection.

9. The thermoelement as recited in claim 8, wherein the thermoelectric layer is geometrically shaped as a hemispherical shell with concave section and a convex section, and wherein the concave section of the hemispherical shell is attached thermally and electrically with the first high power factor electrode.

10. The thermoelement as recited in claim 1 comprising a plurality of micro thermoelements, wherein the plurality of micro thermoelements combine together to form the thermoelement.

11. A method for manufacturing a thermoelement comprising:
etching a base metal layer to form a predetermined shape;
depositing a first high power factor electrode on the base metal layer;
depositing a thermoelectric layer on the first high power factor electrode;
depositing a second high power factor electrode on the thermoelectric layer;
annealing the layered structure comprising the base metal layer, the thermoelectric layer, the first high power electrode, and the second high power factor electrode to form a composition phase; and
depositing a metal layer over the second high power factor electrode.

12. The method as recited in claim 11 further comprising dicing the thermoelement to form units of thermoelements of required dimensions.

13. The method as recited in claim 11 wherein the base metal layer and the metal layer comprises a plurality of metal layers.

14. The method as recited in claim 11, wherein the first and the second high power factor electrode are deposited by physical vapor deposition.

15. The method as recited in claim 11, wherein the thermoelectric layer is deposited by physical vapor deposition.

16. The method as recited in claim 11, wherein the thermoelectric layer is deposited by chemical vapor deposition.

17. The method as recited in claim 11, wherein the metal layer is deposited by electrochemical plating.

18. A thermoelement in a thermoelectric energy convertor for reducing losses at an interface with a thermoelectric material, comprising;
a thermoelectric layer with a first side and a second side;
a first high power factor electrode and a second high power factor electrode, wherein the first side of the thermoelectric layer is attached to the first high power factor electrode the second side of the thermoelectric layer is attached to the second high power factor electrode;
a first metal layer attached to the first high power factor electrode; and
a second metal layer attached to the second high power factor electrode.

19. The thermoelement as recited in claim 18, wherein a hot end is formed at the interface of the first high power factor electrode with the first metal layer and the first side of the thermoelectric layer, and wherein a cold end is formed at an interface of the second high power factor electrode with the second side of the thermoelectric layer and the second metal layer.
